(19) United States
(12) Patent Application Publication
(10) Pub. No.: US 2026/0045957 A1
(43) Pub. Date: Feb. 12, 2026

(54) MICROSCALING FORMAT BLOCKS

(71) Applicant: Meta Platforms Technologies, LLC, Menlo Park, CA (US)

(72) Inventors: Mohammad Janani, San Jose, CA (US); Nanda Unnikrishnan, Sunnyvale, CA (US); Zhaoxia Deng, San Mateo, CA (US); Junqiang Lan, Fremont, CA (US); Adrian Stafford Lewis, Mountain View, CA (US)

(73) Assignee: Meta Platforms Technologies, LLC, Menlo Park, CA (US)

(21) Appl. No.: 19/293,589

(22) Filed: Aug. 7, 2025

Related U.S. Application Data
(60) Provisional application No. 63/680,652, filed on Aug. 8, 2024.

(51) Int. Cl. H03M 7/24; G06F 5/01

(52) U.S. Cl. CPC H03M 7/24; G06F 5/012

(57) ABSTRACT

Disclosed herein are various techniques for converting a vector from a high precision floating point format to a microscaling (MX) format. An example of a precision floating point format is the FP32 format described above, however, the initial format may be another type of standard floating point format as well (reference to the FP32 number format hereinafter is merely for exemplary purposes and not intended to be limiting). The techniques for converting to the MX-compliant format are improvements over the standard technique suggested in the MX specification by at least accounting for the amount of data in the mantissa of the original precision floating point format to mitigate the amount of data that is lost during the conversion. Therefore, the benefits of representing multiple data points of a vector in the single MX format representation without sacrificing as much of the data contained in the original high precision format that may occur following the standard technique described in the MX specification (portions of which are described below).

### CROSS-REFERENCE TO RELATED APPLICATIONS

This application claims priority to and benefit of U.S. provisional patent application No. 63/680,562 filed Aug. 8, 2024, which is herein incorporated by reference.

### BACKGROUND

Artificial intelligence systems require efficient processing of large amounts of data, often involving complex mathematical operations. Floating-point number formats are standardized ways to represent real numbers (numbers with fractional parts) in computing. Floating-point arithmetic plays a crucial role in these computations, with various standards and formats developed to balance precision, range, and computational efficiency.

A floating point number is typically represented in binary representation including a sign bit that indicates the sign of the number (e.g., 0 for positive and 1 for negative), an exponent that determines the scale or magnitude, and a significand or “mantissa” that contains the actual digits of the number being represented. In binary formats, the base is always 2. One example of a floating point format is the FP32 format. This data format includes one sign bit, eight exponent bits, and 23 mantissa (significant) bits. The value formula for FP32 may be (−1)^{sign}*1.mantissa bits*2^{exponent-127}. This is merely one example of a type of floating point number format and other formats also exist.

As one example, an FP32 binary value may be “01000001001100000000000000000000.” Here, the sign bit is “0,” the exponent bits are “10000010,” and the mantissa bits are “01100000000000000000000.” To convert the binary FP32 format into a number, the following steps may be taken. First, the sign may be determined based on the first bit. In this instance, the sign bit is “0,” which indicates that the number is positive (“1” would indicate a negative number). Next, the exponent is determined as the decimal conversion of the exponent bits in the binary (“10000010” is 130 in this example). A bias value of 127 is subtracted from this number (130−127=3). Finally, the mantissa is converted (a leading value of 1 is implicit). In this example, “01100000000000000000000” becomes

$$1 + \frac{0}{{2}^{1}} + \frac{1}{{2}^{2}} + \frac{1}{{2}^{3}} + \frac{0}{{2}^{4}} + … = 1 + 0.25 + 0.125 = 1.375 .$$

Finally, the fully converted number is determined using the values determined in the prior sub-calculations as (−1)⁰*1.375*2^{3=11.0}.

### BRIEF DESCRIPTION OF THE DRAWINGS

FIG. 1 illustrates a first approach for converting a vector to an MX-compliant format, in accordance with one or more embodiments of the disclosure.

FIG. 2 illustrates a second approach for converting a vector to an MX-compliant format, in accordance with one or more embodiments of the disclosure.

FIG. 3 illustrates a third approach for converting a vector to an MX-compliant format, in accordance with one or more embodiments of the disclosure.

FIGS. 4A-4B illustrate methods for converting a vector to an MX-compliant format, in accordance with one or more embodiments of the disclosure.

FIG. 5 illustrates a system for converting a vector to an MX-compliant format, in accordance with one or more embodiments of the disclosure.

FIG. 6 schematically illustrates an example architecture of a computer system, in accordance with one or more embodiments of the disclosure.

The detailed description is set forth with reference to the accompanying drawings. The drawings are provided for purposes of illustration only and merely depict example embodiments of the disclosure. The drawings are provided to facilitate understanding of the disclosure and shall not be deemed to limit the breadth, scope, or applicability of the disclosure. The use of the same reference numerals indicates similar, but not necessarily the same or identical components. Different reference numerals may be used to identify similar components. Various embodiments may utilize elements or components other than those illustrated in the drawings, and some elements and/or components may not be present in various embodiments. The use of singular terminology to describe a component or element may, depending on the context, encompass a plural number of such components or elements and vice versa.

### DETAILED DESCRIPTION

### Overview

Disclosed herein are various techniques for converting data from a high-precision floating point format to a microscaling (MX) format. An example of a high-precision floating point format is the FP32 format described above, however, other formats may also be applicable (accordingly, reference to the FP32 number format hereinafter is merely for exemplary purposes and not intended to be limiting). The techniques for converting to the MX-compliant format are technical improvements over the standard technique suggested in the Open Compute Project (OCP) MX specification by at least accounting for the amount of data in the mantissa of the original precision floating point format to mitigate the amount of data that is lost during the conversion. Therefore, the benefits of representing multiple data points of a vector in the single MX format representation without sacrificing as much of the data contained in the original high precision format that may occur following the standard technique described in the MX specification (portions of which are described below).

The MX format is a floating-point standard designed to offer the precision of traditional floating-point formats while supporting the speed and efficiency needed for large-scale AI computations. MX-compliant formats enable Artificial Intelligence (AI) training and inference with lower bit-width arithmetic operations and smaller memory footprints. This drives hardware performance and efficiency gains that can reduce computational overhead and resource usage. Using data in MX formats in hardware units provides significantly improved performance compared to traditional formats, specifically in generative AI models (e.g., LLMs or other types of models).

MX formats improve performance in AI models for several reasons. First, they provide for a reduced memory footprint. MX formats use 8 or fewer bits per value compared to FP32 (which uses 32 bits). This enables lower memory usage, larger batch sizes on the same hardware, and more models or weights to fit into fast-access memory. Second, MX formats provide lower bandwidth usage. Having fewer bits per number results in less data transferred between memory and compute units. This reduces latency and energy costs as well. Third, they provide faster computation. These formats map directly to specialized low-precision hardware instructions (e.g., NVIDIA tensor cores, Google TPUs, etc.). These units can perform more operations per cycle at 8-bit or lower precision than at FP16 or FP32, for example. Fourth, the formats provide dynamic range via per-tensor/channel scaling.

The MX format is a numerical representation often used in specialized hardware (e.g., neural network accelerators or DSPs) to represent a set of numbers compactly. The format provides a mechanism for representing multiple values of a vector more efficiently. An MX-complaint format is characterized by three components (illustrated below): (1) scale (“2^{X}”) data type/encoding (a shared exponent or scale factor that is common to a group of numbers), (1) private elements (pᵢ) data type/encoding (multiple floating point values, one for each number), and (3) scaling block size (“k”). The technique described herein specifically pertains to an improved approach for determining the scale (“2^{X}”) of these three components of the MX format. Microscaling (especially block floating point or log-based MX formats) applies scale factors per tensor or per group. This provides higher effective dynamic range than fixed-point integers, with low precision overhead. This also mitigates the problem of precision loss in low-bit formats.

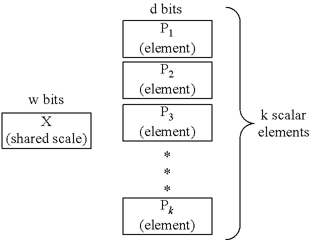

All k elements (pᵢ) have the same data type and, therefore, the same bit-width. The scale factor is shared across all k elements. The data types of the elements and scale are chosen independently. In this sense, MX can be seen as a mechanism to build a vector data type from scalar data types. The bit widths are represented by the symbols “w” and “d”. The “w” symbol represents the number of bits used to encode the shared scale X, and the “d” symbol represents the number of bits used to represent each element pᵢ. Therefore, each block of k elements can be encoded in (w+kd) bits. If multiple blocks share the same scale factor, an implementation can compress or prune away the repeated scale factors. An implementation can store the scale factor contiguously with or separately from the k elements.

The OCP MX specification recommends the following way to convert a vector of scalar elements from high precision to MX-compliant formats, which should be minimally supported in hardware:

A mechanism must be provided for converting a k-length vector

$$V {: [ {V}_{i} ]}_{i = 1}^{k}$$

of scalar elements to an MX-compliant format

$$\{ X , {[ {P}_{i} ]}_{i = 1}^{k} \}$$

by producing the block scale X and the elements pᵢ. In particular, the following semantics should be minimally supported:
1. Set X to be the largest power-of-two 1 less than or equal to

$${max}_{{V}_{i} ϵ V} ( \vert {V}_{i} \vert ) ,$$

divided by the largest power-of-two representable in the element data type.
2. Set pᵢ to be the scaled inputs Vi/X quantized to the element data type. For this quantization, normal numbers that exceed the maximum normal representation of the element data type should be clamped to the maximum normal, preserving the sign.

Embodiments of the present disclosure provide a more comprehensive and effective solution for conversion from a high-precision floating point number format (such as FP32, as one non-limiting example) to an MX number format. More specifically, embodiments present a block scaler for microscaling shared block format and provide techniques for determining how to select the block scale (2^{X}) and round/clamp each scalar element, pᵢ.

As a first option for determining the block scale of the MX format, Equation 1 (shown below) may be used:

$${2}^{X} = {2}^{floor ( {log}_{2} ( max ( \vert {v}_{i} \vert ) ) - maxExp )} \qquad ( Equation 1 )$$

In Equation 1, vᵢ represents the data (for example, if there are 32 data points in a given vector, v, then there would be v₀ to v₃₁ values, with each vᵢ representing one of the data points in the vector). The “maxExp” (an exemplary variable name for the maximum exponent) is a fixed number that depends on the particular MX format that is being used (for example, the maxExp for the MX4 format is different than the maxExp for the MX8 format, two specific types of MX formats). The “floor” operation indicates that the decimal portion of the resulting value is removed. For example, if the resulting value from (log ₂ (max(|vᵢ|))−maxExp) is 4.6, then floor (4.6) is 4. Likewise, floor (4.99) would also be 4, as another example.

Similar to the method described in the MX specification (as described above), this first option selects the maximum absolute scalar element of the original vector (e.g., one of the data points in the vector) and then subtracts the maximum exponent in the scalar element data type (e.g., maxExp=2 in MX4 E2M1 and 4 in MX4 E3M0) as the shared exponent. This method is hardware-efficient. However, the maximum absolute element might get clamped to the maximum representable value (that is, some data may be lost) with the scalar element data type due to the cutoff on the mantissa bits in the MX format. That is, the number of mantissa bits in the MX format may be less than the number of mantissa bits in the original higher precision floating point format (such as FP32, as a non-limiting example). If the mantissa bit width is low, such as MX4 E2M1 and MX4 E3M0, the large numbers (or outliers) can get cut off and impact the quantization accuracy significantly.

This is the most straightforward approach for determining the block scale, in which only the minimum and maximum values of the exponents are determined, and then the original data format is down converted to the MX format. In the illustrative examples shown below, a maximum exponent of 3 is used, and down conversion may be performed as follows:

$${d}_{max} = {2}^{3} * 1 ( FP 32 ) -> {d}^{′} = 2 * {2}^{2} * 1 \qquad Example 1$$

$${d}_{max} = {2}^{3} * 1.5 ( FP 32 ) -> {d}^{′} = 2 * {2}^{2} * 1.5 \qquad Example 2$$

$${d}_{max} = {2}^{3} * 1.75 ( FP 32 ) -> {d}^{′} = 2 * {2}^{2} \qquad Example 3$$

In these examples (and the examples provided for Equations 2 and 3), the first value in dₘₐₓ is the maximum exponent in the original vector and the second value is 1.m. Additionally, the first number in the d′ value represents the block factor 2^{X}, where X=maxExp−2=1 (X=3−2=1 in this example). The first values in all three examples are 2¹ because the values are rounded down by the floor operation in Equation 1. That is, the values are always rounded down regardless of the mantissa value. Example: 2⁻¹⁰⁰*1.9->maxExp=−100->X=−100−2=−102->2^{2*}1.5. The second and third values are the exponent of the data and the mantissa (1.m) of the data. Here, the first value is primarily of interest given that the technique described herein is used to determine the “X” (or 2^{X}) value.

As a second option for determining the block scale, Equation 2 shown below may be used:

$${2}^{X} = {2}^{ceil ( {log}_{2} ( max ( \vert {v}_{i} \vert ) ) - maxExp )} \qquad ( Equation 2 )$$

In Equation 2, “ceil” operates in the opposite manner as “floor” in Equation 1. For example, floor(4.1) would be 4 and ceil(4.1) would be 5. Similarly, floor(4.6) would be 4 and ceil(4.6) would be 5. To avoid the cutoff on large magnitudes that may occur with Equation 1, Equation 2 uses the smallest power-of-two that is equal to or larger than the max (|vᵢ|) scaled by the scalar element maximum power of 2 (another way of saying the “ceil” of the values in parentheses in Equation 2. This maintains max (|vᵢ|) within the representable range of values in the MX format, but smaller magnitudes may get shifted to 0 due to the larger shared exponent.

This is similar to the first option, but with an adjustment to avoid clipping the maximum value. Particularly, the minimum and maximum values (in other words, the maximum value after the absolute value is applied to the values) of the exponents are determined and added to a value of 1. The data is then down converted to the MX format. As illustrative examples, the adjusted exponent may be 3+1=4 (the maximum) and down conversion may be performed as follows:

$${d}_{max} = {2}^{3} * 1 ( FP 32 ) -> {d}^{′} = {2}^{2} * {2}^{1} * 1 \qquad Example 1$$

$${d}_{max} = {2}^{3} * 1.5 ( FP 32 ) -> {d}^{′} = {2}^{2} * {2}^{1} * 1.5 \qquad Example 2$$

$${d}_{max} = {2}^{3} * 1.75 ( FP 32 ) -> {d}^{′} = {2}^{2} * {2}^{2} * 1. \qquad Example 3$$

Where X=adj_max_expo−2=2 and adj_max_expo=max_expo+1. In these examples, the first values in all three examples are 2² because the values are rounded up by the ceil operation in Equation 2. That is, the values are always rounded up regardless of the mantissa value.

As a third option for determining the block scale, Equation 3 shown below may be used:

$${2}^{X} = {2}^{floor ( {log}_{2} ( rounding ( max ( \vert {v}_{i} \vert ) ) ) - maxExp )} \qquad ( Equation 3 )$$

The third option is a solution that includes first rounding the maximum scalar element to the target mantissa bit width, with round to nearest even (RNE) or stochastic rounding (SR). Then, the exponent is used after rounding to calculate the scaling factor (similar to the first option, described above). As the shared exponent selection is dependent on the rounded values, this can avoid clamping the large magnitudes resulting from the cutoff on the mantissa bits, and also preserves the smaller magnitudes. In some implementations, because of the low mantissa bit-width, rounding the max scalar element to the nearest integer value is used. In some implementations, because of the low mantissa bit-width, stochastic rounding is used.

That is, to address the potential downsides of the first two options, this third option provides an adaptive method to adjust the maximum exponent value used in the calculation of X. In this regard, the system determines the value of the. If 1.m is less than 1.75, then the maximum exponent is adjusted to calculate X (the log 2 of the rounded maximum value of the block data). Otherwise, if 1.m is greater than or equal to 1.75, one is added to the maximum exponent. In other words, if the mantissa value is greater than the threshold (in which case data would be lost when converting to the MX format), then the exponent is increased. This value is selected because it is the maximum representable value in the destination format (the MX format). However, this is not necessarily limiting, and a different threshold may be used (other than 1.75) if a particular MX format has a different maximum representable value. For 1.m, the “m” refers to all of the information in the mantissa bits of the original data format. For the examples shown below, the maximum exponent of the values in the vector is 3 and down conversion may be performed as follows:

$${d}_{max} = {2}^{3} * 1 ( FP 32 ) -> {d}^{′} = 2 * {2}^{2} * 1 \qquad Example 1$$

$${d}_{max} = {2}^{3} * 1.5 ( FP 32 ) -> {d}^{′} = 2 * {2}^{2} * 1.5 \qquad Example 2$$

$${d}_{max} = {2}^{3} * 1.75 ( FP 32 ) -> {d}^{′} = {2}^{2} * {2}^{2} \qquad Example 3$$

The first values for the first two examples are 2¹ because the values are rounded down and the first value in the third example is 2² because the value rounded up (because the 1.m value is 1.75 (which satisfies the greater than or equal to 1.75 condition). In this way, the dynamic range is maximized while clipping is avoided. However, the cost is to consider the first two MSB bits of the mantissa to calculate the adjusted max exponent.

### Illustrative Embodiments and Use Cases

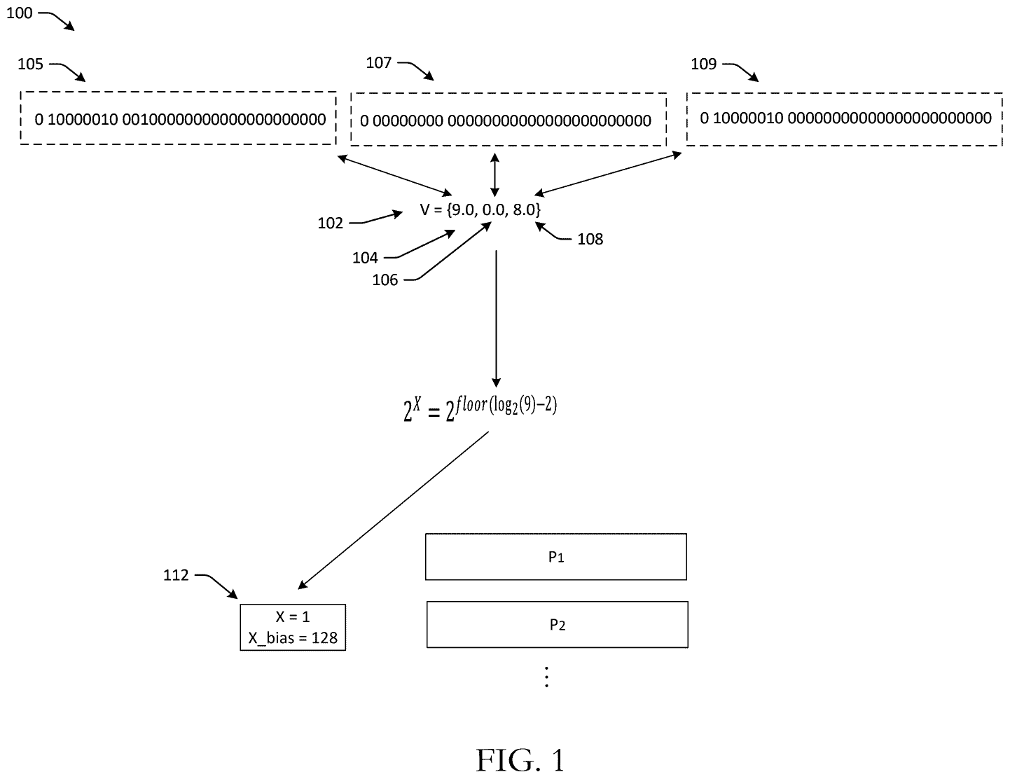

FIG. 1 depicts a flow diagram 100 illustrating an example of the first approach (the first option associated with Equation 1 described above) for converting a vector including data initially represented in a high-precision floating point format to an MX-compliant format. The flow diagram 100 shows a vector 102 including three different values (for simplicity's sake, the vector may include any other number of values) of v₀=9.0, v₁=0,0, and v₂=8.0. FIG. 1 also shows the FP32 binary format representations of these three vector values. For example, the first binary value 105 is the FP32 format representation of the 9.0 value, the second binary value 107 is the FP32 format representation of the 0.0 value, and the third binary value 109 is the FP32 format representation of the 8.0 value. As indicated above, the first bit is the sign bit, the next 8 bits are the exponent bits, and the remaining bits are the mantissa bits. As an illustrative example, for the first binary value 105, the mantissa is

$$1 + \frac{0}{{2}^{1}} + \frac{0}{{2}^{2}} + \frac{1}{{2}^{3}} + \frac{0}{{2}^{4}} + … = 1 + 0 + 0 + \text{.125} = 1.125 .$$

Therefore, using the equation described above for determining the decimal value from the binary FP32 value, (−1)⁰*1.125*2¹³⁰⁻¹²⁷=9.

To determine the “X,” the first step in the first option is to determine the maximum value within the vector and then determine the exponent of that maximum value. In this case, the maximum value is 9. This maximum value is then inserted into Equation 1 along with the maxExp value of 2 (the assumption in this example is that the MX4 format is used, however, the maxExp value would differ if another MX format is used, as indicated above. The log ₂ (9)−2=1.169925. The floor of this value is 1 Therefore, X=1. The resulting scale 112 for the vector in the MX format is shown at the bottom of FIG. 1. This X value of 1 is the “unbiased” value. The biased value would be 1+127=128. The resulting scale of 2\hat{ }X=2\hat{ }1, as shown in the bottom of FIG. 1. However, in memory storage, the values are saved by biased block scaler exponent values (e.g., before the power of 2 calculations). Hnece, the biased value is also shown.

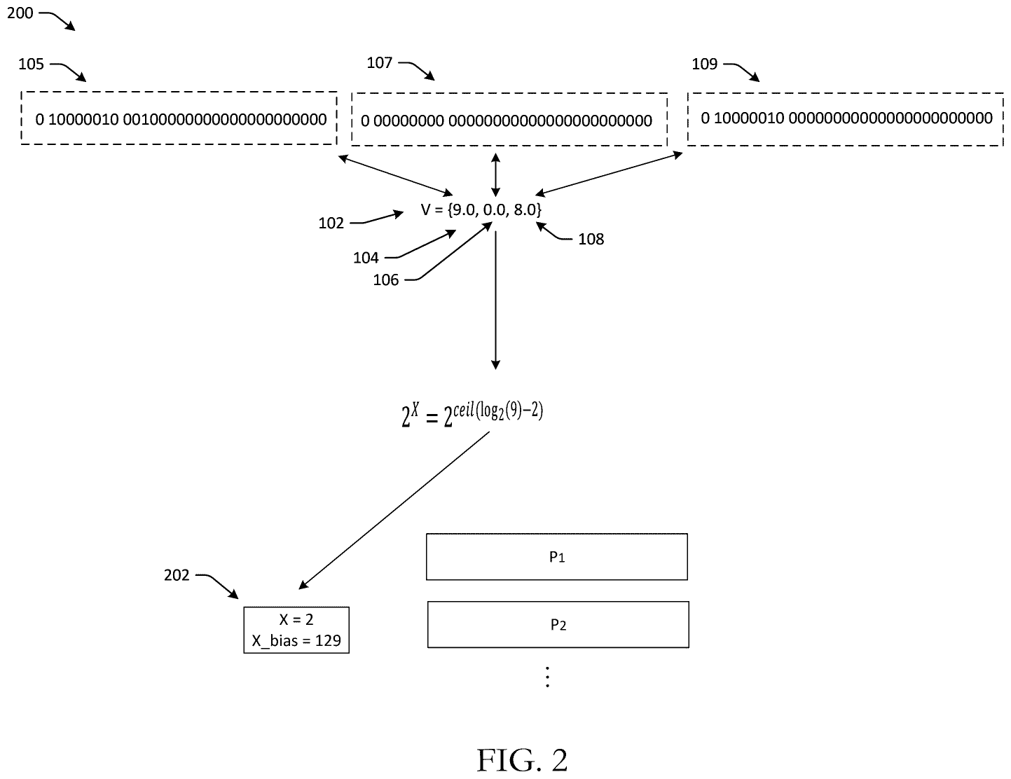

FIG. 2 depicts a flow diagram 200 illustrating an example of the second approach (the second option associated with Equation 2 described above) for converting a vector including data initially represented in a high-precision floating point format to an MX-compliant format. For consistency's sake, the flow diagram 200 shows the same vector 102 including the same three different values of v₀=9.0, v₁=0,0, and v₂=8.0. The same maximum value of 9 is determined in a similar manner described above with respect to the flow diagram 100 of FIG. 1. However, this maximum value and the maxExp value for the MX4 format are inserted into Equation 2 instead of Equation 1 in this flow diagram 200. Again, the log ₂ (9)−2=1.169925. The ceil of this value is 2. Therefore, X=2. The resulting scale 202 for the vector in the MX format is shown at the bottom of FIG. 2. This X value of 2 is the “unbiased” value. The biased value would be 2+127=129. The resulting scale of 2\hat{ }X=2\hat{ }2, as shown in the bottom of FIG. 2.

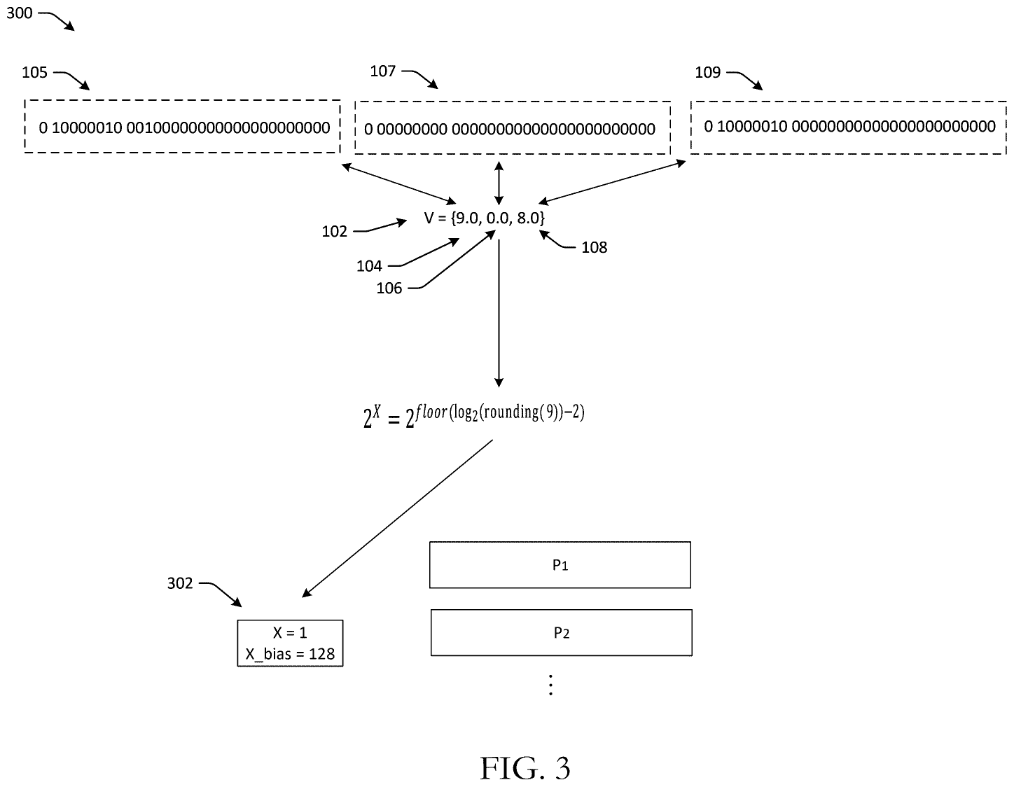

FIG. 3 depicts a flow diagram 300 illustrating an example of the third approach (the second option associated with Equation 3 described above) for converting a vector including data initially represented in a high-precision floating point format to an MX-compliant format. For consistency's sake, the flow diagram 300 shows the same vector 102 including the same three different values of v₀=9.0, v₁=0,0, and v₂=8.0. The same maximum value of 9 is determined in a similar manner described above with respect to the flow diagram 100 of FIG. 1. However, this maximum value and the maxExp value for the MX4 format are inserted into Equation 3 instead of Equation 1 in this flow diagram 300. Again, the log ₂ (9)−2=1.169925 (because the 1.m value is less than the threshold of 1.75 (again, this threshold may vary). The floor of this value is 1. Therefore, X=1. The resulting scale 302 for the vector in the MX format is shown at the bottom of FIG. 3. This X value of 1 is the “unbiased” value. The biased value would be 1+127=129. The resulting scale of 2\hat{ }X=2\hat{ }1, as shown in the bottom of FIG. 1.

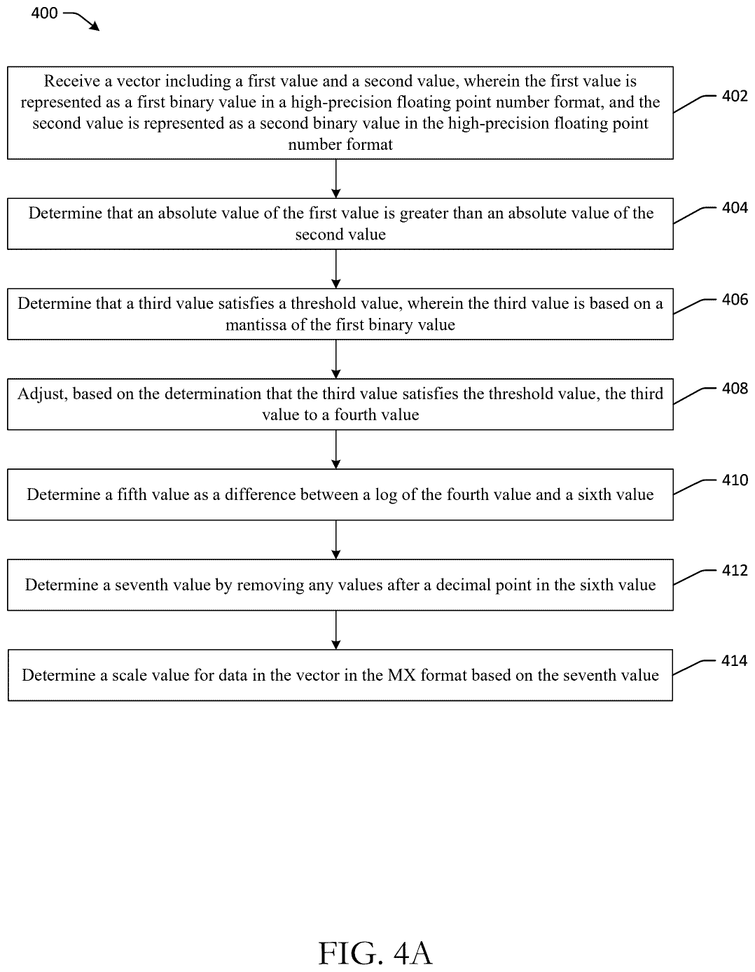

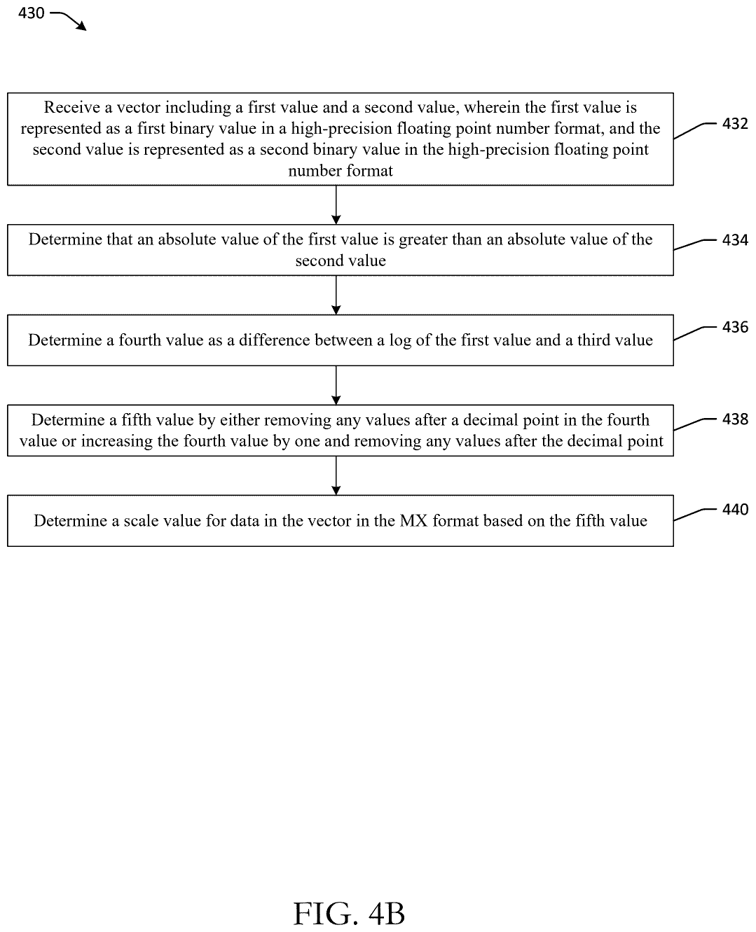

FIGS. 4A-4B depict example methods 400 and 430 for converting a vector to an MX-compliant format. Specifically, the method 400 of FIG. 4A pertains to the third option described above and the method 430 of FIG. 4B pertains to the first and second options. Some or all of the blocks of the process flows or methods in this disclosure may be performed in a distributed manner across any number of devices or systems (for example, client system 530, backend system 560 (including hardware compute units 562 (or any other number of hardware compute units), computing system 600, etc.). The operations of the methods 400 and 430 may be optional and may be performed in a different order.

Beginning with the method 400 of FIG. 4A, the approach associated with the third option is shown. At block 402 of the method 400, computer-executable instructions stored in memory of a system or device may be executed to receive a vector including a first value and a second value, wherein the first value is represented as a first binary value in a high-precision floating point number format, and the second value is represented as a second binary value in the high-precision floating point number format. For example, the vector may include values represented in an initial number format, such as a high precision floating point format (e.g., FP32, etc.) that is to be converted into an MX-compatible format, as described herein. Although reference is made to the vector including a first value and a second value, the vector may also include any other number of values. Each “value” may represent a data point within the vector. For example, if the vector, v, has two data points, the first value may be v₀ and the second value may be v₁.

At block 404 of the method 400, computer-executable instructions stored in memory of a system or device may be executed to determine that an absolute value of the first value is greater than an absolute value of the second value. As described above, this refers to determining the maximum value of the absolute value of the data points in the vector. In this case, the absolute value of the first data point is larger than the absolute value of the second data point (for example, the first data point may have a value of 9 and the second data point may have a value of 5).

At block 406 of the method 400, computer-executable instructions stored in memory of a system or device may be executed to determine that a third value satisfies a threshold value, wherein the third value is based on a mantissa of the first binary value. At block 408 of the method 400, computer-executable instructions stored in memory of a system or device may be executed to adjust, based on the determination that the third value satisfies the threshold value, the third value to a fourth value.

In this case, the third value “satisfying the threshold value” may refer to the third value being greater than or equal to the threshold value. For example, the third value may be the “1.m” value described above. Additionally, the threshold value may be 1.75, for example. Additionally, adjusting the third value may refer to adding one to the third value. Accordingly, if 1.m is greater than or equal to 1.75, then the fourth value is determined as the third value added to one. In other words, if the mantissa value is greater than the threshold (in which case data would be lost when converting to the MX format), then the exponent is increased. This value is selected because it is the maximum representable value in the destination format (the MX format). However, as mentioned above, 1.75 is merely exemplary and other thresholds may also be used.

At block 410 of the method 400, computer-executable instructions stored in memory of a system or device may be executed to determine a fifth value as a difference between a log of the fourth value and a sixth value. For example, the fifth value may be determined as “log ₂ (rounding(max(|vᵢ|)))−maxExp)” of Equation 3.

At block 412 of the method 400, computer-executable instructions stored in memory of a system or device may be executed to determine a seventh value by removing any values after a decimal point in the sixth value. That is, the eighth value may be the result of the floor operation included in Equation 3 that is performed with the seventh value.

At block 414 of the method 400, computer-executable instructions stored in memory of a system or device may be executed to determine a scale value for data in the vector in the MX format based on the seventh value. For example, the scale value may be determined based on 2\hat{ }X, where X is the seventh value based on Equation 3).

Turning to the method 430 of FIG. 4B, the approach associated with the first and second options are shown (the method 430 covers both options). The method 430 may include at least some similar blocks as the method 400. For example, blocks 432-440 may be similar to blocks 402-410. That is, at block 432 of the method 430, computer-executable instructions stored in memory of a system or device may be executed to receive a vector including a first value and a second value, wherein the first value is represented as a first binary value in a high-precision floating point number format, and the second value is represented as a second binary value in the high-precision floating point number format. At block 434 of the method 430, computer-executable instructions stored in memory of a system or device may be executed to determine that an absolute value of the first value is greater than an absolute value of the second value. At block 436 of the method 430, computer-executable instructions stored in memory of a system or device may be executed to determine a fourth value as a difference between a log of the first value and a third value. For example, the fourth value may be determined by log ₂ (max(|vᵢ|))−maxExp) of Equations 1 and 2.

At block 438 of the method 430, computer-executable instructions stored in memory of a system or device may be executed to determine a fifth value by either removing any values after a decimal point in the fourth value or increasing the fourth value by one and removing any values after the decimal point. For example, removing any values after a decimal point in the fourth value may refer to the floor operation of Equation 1. Likewise, increasing the fourth value by one and removing any values after the decimal point may refer to the ceil operation of Equation 2.

At block 440 of the method 430, computer-executable instructions stored in memory of a system or device may be executed to determine a scale value for data in the vector in the MX format based on the fifth value.

One or more illustrative embodiments of the disclosure have been described above. The above-described embodiments are merely illustrative of the scope of this disclosure and are not intended to be limiting in any way. Accordingly, variations, modifications, and equivalents of the embodiments disclosed herein are also within the scope of this disclosure. The above-described embodiments and additional and/or alternative embodiments of the disclosure will be described in detail hereinafter through reference to the accompanying drawings.

One or more operations of the methods, process flows, or use cases of FIGS. 1-4B may have been described above as being performed by a computing system, or more specifically, by one or more program module(s), applications, or the like executing on a device. It should be appreciated, however, that any of the operations of the methods, process flows, or use cases of FIGS. 1-4B may be performed, at least in part, in a distributed manner by one or more other devices, or more specifically, by one or more program module(s), applications, or the like executing on such devices. In addition, it should be appreciated that processing performed in response to the execution of computer-executable instructions provided as part of an application, program module, or the like may be interchangeably described herein as being performed by the application or the program module itself or by a device on which the application, program module, or the like is executing. While the operations of the methods, process flows, or use cases of FIGS. 1-4B may be described in the context of the illustrative devices, it should be appreciated that such operations may be implemented in connection with numerous other device configurations.

The operations described and depicted in the illustrative methods, process flows, and use cases of FIGS. 1-4B may be carried out or performed in any suitable order, such as the depicted orders, as desired in various example embodiments of the disclosure. Additionally, in certain example embodiments, at least a portion of the operations may be carried out in parallel. Furthermore, in certain example embodiments, less, more, or different operations than those depicted in FIGS. 1-4B may be performed.

Although specific embodiments of the disclosure have been described, one of ordinary skill in the art will recognize that numerous other modifications and alternative embodiments are within the scope of the disclosure. For example, any of the functionality and/or processing capabilities described with respect to a particular device or component may be performed by any other device or component. Further, while various illustrative implementations and architectures have been described in accordance with embodiments of the disclosure, one of ordinary skill in the art will appreciate that numerous other modifications to the illustrative implementations and architectures described herein are also within the scope of this disclosure.

Certain aspects of the disclosure are described above with reference to block and flow diagrams of systems, methods, apparatuses, and/or computer program products according to example embodiments. It will be understood that one or more blocks of the block diagrams and flow diagrams, and combinations of blocks in the block diagrams and the flow diagrams, respectively, may be implemented by the execution of computer-executable program instructions. Likewise, some blocks of the block diagrams and flow diagrams may not necessarily need to be performed in the order presented, or may not necessarily need to be performed at all, according to some embodiments. Further, additional components and/or operations beyond those depicted in blocks of the block and/or flow diagrams may be present in certain embodiments.

Accordingly, blocks of the block diagrams and flow diagrams support combinations of means for performing the specified functions, combinations of elements or steps for performing the specified functions, and program instruction means for performing the specified functions. It will also be understood that each block of the block diagrams and flow diagrams, and combinations of blocks in the block diagrams and flow diagrams, may be implemented by special-purpose, hardware-based computer systems that perform the specified functions, elements or steps, or combinations of special-purpose hardware and computer instructions.

### Illustrative Computer Architecture

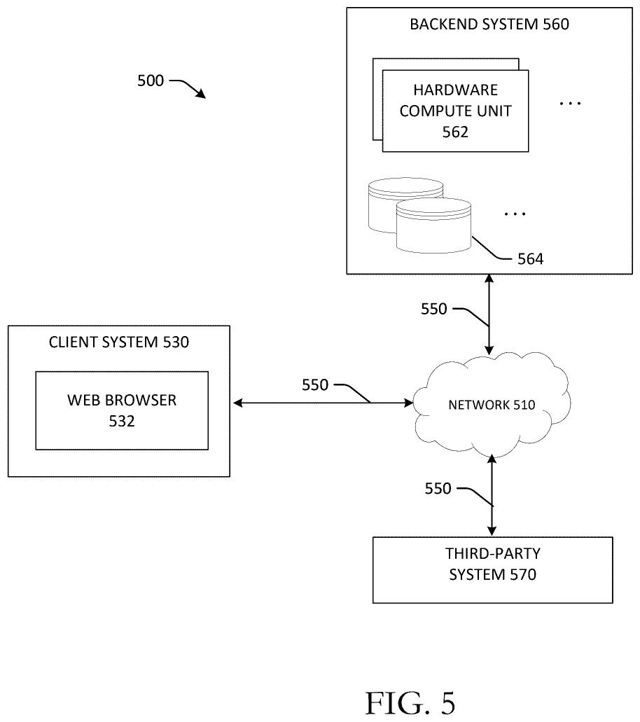

FIG. 5 illustrates an example network environment 500 associated with a block-based iterative one-pass processing system for determining variance and mean as described herein. Network environment 500 may implement one or more aspects of the flow diagrams 200 and the method 300 already discussed.

Network environment 500 includes a client system 530, a backend system 560, and a third-party system 570 connected to each other by a network 510. Although the figures illustrate a particular arrangement of client system 530, backend system 560, third-party system 570, and network 510, this disclosure contemplates any suitable arrangement of client system 530, backend system 560, third-party system 570, and network 510. As an example and not by way of limitation, two or more of client system 530, backend system 560, and third-party system 570 may be connected to each other directly, bypassing network 510. As another example, two or more of client system 530, backend system 560, and third-party system 570 may be physically or logically co-located with each other in whole or in part. Moreover, although FIG. 5 illustrates a particular number of client systems 530, backend systems 560, third-party systems 570, and networks 510, this disclosure contemplates any suitable number of client systems 530, backend systems 560, third-party systems 570, and networks 510. As an example and not by way of limitation, network environment 500 may include multiple client systems 530, backend systems 560, third-party systems 570, and networks 510. Furthermore, although reference is made specifically to a backend system 560, the block-based iterative one-pass processing technique described herein may be applicable to any other type of system as well.

This disclosure contemplates any suitable network 510. As an example and not by way of limitation, one or more portions of network 510 may include an ad hoc network, an intranet, an extranet, a virtual private network (VPN), a local area network (LAN), a wireless LAN (WLAN), a wide area network (WAN), a wireless WAN (WWAN), a metropolitan area network (MAN), a portion of the Internet, a portion of the Public Switched Telephone Network (PSTN), a cellular telephone network, or a combination of two or more of these.

Network 510 may include one or more networks 510. Links 550 may connect client system 530, backend system 560, and third-party system 570 to communication network 510 or to each other. This disclosure contemplates any suitable links 550. In particular examples, one or more links 550 include one or more wireline (such as for example Digital Subscriber Line (DSL) or Data Over Cable Service Interface Specification (DOCSIS)), wireless (such as for example Wi-Fi or Worldwide Interoperability for Microwave Access (WiMAX)), or optical (such as for example Synchronous Optical Network (SONET) or Synchronous Digital Hierarchy (SDH)) links. In particular examples, one or more links 550 each include an ad hoc network, an intranet, an extranet, a VPN, a LAN, a WLAN, a WAN, a WWAN, a MAN, a portion of the Internet, a portion of the PSTN, a cellular technology-based network, a satellite communications technology-based network, another link 550, or a combination of two or more such links 550. Links 550 need not necessarily be the same throughout network environment 500. One or more first links 550 may differ in one or more respects from one or more second links 550.

In particular examples, client system 530 may be an electronic device including hardware, software, or embedded logic components or a combination of two or more such components and capable of carrying out the appropriate functionalities implemented or supported by client system 530. As an example and not by way of limitation, a client system 530 may include a computer system such as a desktop computer, notebook or laptop computer, netbook, a tablet computer, e-book reader, GPS device, camera, personal digital assistant (PDA), handheld electronic device, cellular telephone, smartphone, augmented/virtual reality device, other suitable electronic device, or any suitable combination thereof. This disclosure contemplates any suitable client systems 530. A client system 530 may enable a network user at client system 530 to access network 510. A client system 530 may enable its user to communicate with other users at other client systems 530.

In particular examples, client system 530 may include a web browser 532, such as MICROSOFT INTERNET EXPLORER, GOOGLE CHROME or MOZILLA FIREFOX, and may have one or more add-ons, plug-ins, or other extensions, such as TOOLBAR or YAHOO TOOLBAR. A user at client system 530 may enter a Uniform Resource Locator (URL) or other address directing the web browser 532 to a particular server, and the web browser 532 may generate a Hyper Text Transfer Protocol (HTTP) request and communicate the HTTP request to server. The server may accept the HTTP request and communicate to client system 530 one or more Hyper Text Markup Language (HTML) files responsive to the HTTP request. Client system 530 may render a webpage based on the HTML files from the server for presentation to the user. This disclosure contemplates any suitable webpage files. As an example and not by way of limitation, webpages may render from HTML files, Extensible Hyper Text Markup Language (XHTML) files, or Extensible Markup Language (XML) files, according to particular desires. Such pages may also execute scripts such as, for example and without limitation, those written in JAVASCRIPT, JAVA, MICROSOFT SILVERLIGHT, combinations of markup language and scripts such as AJAX (Asynchronous JAVASCRIPT and XML), and the like. Herein, reference to a webpage encompasses one or more corresponding webpage files (which a browser may use to render the webpage) and vice versa, where appropriate.

In particular examples, the network environment 500 may include backend system 560 including one or more hardware compute units 562. The hardware compute units 562 may be specialized hardware that are configured to perform computations using data represented in a floating point format (such as FP32, for example) or an MX format as described herein. For example, the hardware compute units 562 may be configured to perform Artificial Intelligence (AI) training and inference computations (such as matrix multiplications, etc.). However, the hardware compute units 562 are not necessarily limited to Artificial Intelligence (AI) training and inference computations, and the data in the formats described herein may be used for other types of use cases.

Although FIG. 5 shows the hardware compute units 562 being associated with a backend system 560, the hardware compute units 562 may also be located anywhere else in the networking environment 500. Data stores 564 may be used to store various types of information. In particular examples, the information stored in data stores 564 may be organized according to specific data structures. In particular examples, each data store 564 may be a relational, columnar, correlation, or other suitable database.

Although this disclosure describes or illustrates particular types of databases, this disclosure contemplates any suitable types of databases. Particular examples may provide interfaces that enable a client system 530, a backend system 560, or a third-party system 570 to manage, retrieve, modify, add, or delete the information stored in data store 564.

In particular examples, a third-party system 570 may include one or more types of servers, one or more data stores, one or more interfaces, including but not limited to APIs, one or more web services, one or more content sources, one or more networks, or any other suitable components, e.g., that servers may communicate with. A third-party system 570 may be operated by a different entity from an entity operating backend system 560.

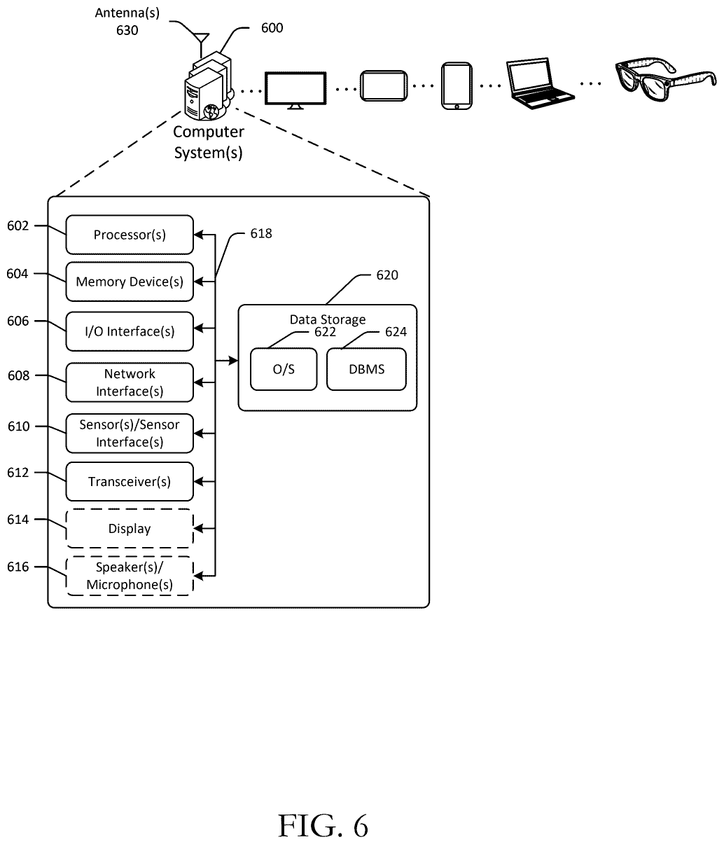

FIG. 6 is a schematic block diagram of one or more illustrative computing system(s) 600 in accordance with one or more example embodiments of the disclosure. The computing system(s) 600 may include any suitable computing device including, but not limited to, a server system, a voice interaction device, a mobile device such as a smartphone, a tablet, an e-reader, a wearable device, or the like; a desktop computer; a laptop computer; a content streaming device; or the like. The computing system(s) 600 may correspond to an illustrative device configuration for the device(s) of FIGS. 1-5 (such as client system 530, backend system 560, third-party system 570, and systems and/or devices used to perform or facilitate the performance of any processes associated with the flow diagrams of FIGS. 1-4B, etc.).

The computing system(s) 600 may be configured to communicate via one or more networks. Such network(s) may include, but are not limited to, any one or more different types of communications networks such as, for example, cable networks, public networks (e.g., the Internet), private networks (e.g., frame-relay networks), wireless networks, cellular networks, telephone networks (e.g., a public switched telephone network), or any other suitable private or public packet-switched or circuit-switched networks. Further, such network(s) may have any suitable communication range associated therewith and may include, for example, global networks (e.g., the Internet), metropolitan area networks (MANs), wide area networks (WANs), local area networks (LANs), or personal area networks (PANs). In addition, such network(s) may include communication links and associated networking devices (e.g., link-layer switches, routers, etc.) for transmitting network traffic over any suitable type of medium including, but not limited to, coaxial cable, twisted-pair wire (e.g., twisted-pair copper wire), optical fiber, a hybrid fiber-coaxial (HFC) medium, a microwave medium, a radio frequency communication medium, a satellite communication medium, or any combination thereof.

In an illustrative configuration, the computing system(s) 600 may include one or more processors (processor(s)) 602, one or more memory devices 604 (also referred to herein as memory 604), one or more input/output (I/O) interface(s) 606, one or more network interface(s) 608, one or more sensor(s) or sensor interface(s) 610, one or more transceiver(s) 612, one or more optional display(s) 614, one or more optional microphone(s) 616, and data storage 620. The computing system(s) 600 may further include one or more bus(es) 618 that functionally couple various components of the computing system(s) 600. The computing system(s) 600 may further include one or more antenna(s) 630 that may include, without limitation, a cellular antenna for transmitting or receiving signals to/from a cellular network infrastructure, an antenna for transmitting or receiving Wi-Fi signals to/from an access point (AP), a Global Navigation Satellite System (GNSS) antenna for receiving GNSS signals from a GNSS satellite, a Bluetooth antenna for transmitting or receiving Bluetooth signals, a Near Field Communication (NFC) antenna for transmitting or receiving NFC signals, and so forth. These various components will be described in more detail hereinafter.

The bus(es) 618 may include at least one of a system bus, a memory bus, an address bus, or a message bus, and may permit the exchange of information (e.g., data (including computer-executable code), signaling, etc.) between various components of the computing system(s) 600. The bus(es) 618 may include, without limitation, a memory bus or a memory controller, a peripheral bus, an accelerated graphics port, and so forth. The bus(es) 618 may be associated with any suitable bus architecture including, without limitation, an Industry Standard Architecture (ISA), a Micro Channel Architecture (MCA), an Enhanced ISA (EISA), a Video Electronics Standards Association (VESA) architecture, an Accelerated Graphics Port (AGP) architecture, a Peripheral Component Interconnect (PCI) architecture, a PCI-Express architecture, a Personal Computer Memory Card International Association (PCMCIA) architecture, a Universal Serial Bus (USB) architecture, and so forth.

The memory 604 of the computing system(s) 600 may include volatile memory (memory that maintains its state when supplied with power) such as random access memory (RAM) and/or non-volatile memory (memory that maintains its state even when not supplied with power) such as read-only memory (ROM), flash memory, ferroelectric RAM (FRAM), and so forth. Persistent data storage, as that term is used herein, may include non-volatile memory. In certain example embodiments, volatile memory may enable faster read/write access than non-volatile memory. However, in certain other example embodiments, certain types of non-volatile memory (e.g., FRAM) may enable faster read/write access than certain types of volatile memory.

In various implementations, the memory 604 may include multiple different types of memory such as various types of static random access memory (SRAM), various types of dynamic random access memory (DRAM), various types of unalterable ROM, and/or writeable variants of ROM such as electrically erasable programmable read-only memory (EEPROM), flash memory, and so forth. The memory 604 may include main memory as well as various forms of cache memory such as instruction cache(s), data cache(s), translation lookaside buffer(s) (TLBs), and so forth. Further, cache memory such as a data cache may be a multi-level cache organized as a hierarchy of one or more cache levels (L1, L2, etc.).

The data storage 620 may include removable storage and/or non-removable storage including, but not limited to, magnetic storage, optical disk storage, and/or tape storage. The data storage 620 may provide non-volatile storage of computer-executable instructions and other data. The memory 604 and the data storage 620, removable and/or non-removable, are examples of computer-readable storage media (CRSM) as that term is used herein.

The data storage 620 may store computer-executable code, instructions, or the like that may be loadable into the memory 604 and executable by the processor(s) 602 to cause the processor(s) 602 to perform or initiate various operations. The data storage 620 may additionally store data that may be copied to the memory 604 for use by the processor(s) 602 during the execution of the computer-executable instructions. Moreover, output data generated as a result of execution of the computer-executable instructions by the processor(s) 602 may be stored initially in the memory 604, and may ultimately be copied to the data storage 620 for non-volatile storage.

More specifically, the data storage 620 may store one or more operating systems (O/S) 622; one or more database management systems (DBMS) 624; and one or more program module(s), applications, engines, computer-executable code, scripts, or the like. Some or all of these module(s) may be sub-module(s). Any of the components depicted as being stored in the data storage 620 may include any combination of software, firmware, and/or hardware. The software and/or firmware may include computer-executable code, instructions, or the like that may be loaded into the memory 604 for execution by one or more of the processor(s) 602. Any of the components depicted as being stored in the data storage 620 may support functionality described in reference to corresponding components named earlier in this disclosure.

The data storage 620 may further store various types of data utilized by the components of the computing system(s) 600. Any data stored in the data storage 620 may be loaded into the memory 604 for use by the processor(s) 602 in executing computer-executable code. In addition, any data depicted as being stored in the data storage 620 may potentially be stored in one or more datastore(s) and may be accessed via the DBMS 624 and loaded in the memory 604 for use by the processor(s) 602 in executing computer-executable code. The datastore(s) may include, but are not limited to, databases (e.g., relational, object-oriented, etc.), file systems, flat files, distributed datastores in which data is stored on more than one node of a computer network, peer-to-peer network datastores, or the like.

The processor(s) 602 may be configured to access the memory 604 and execute the computer-executable instructions loaded therein. For example, the processor(s) 602 may be configured to execute the computer-executable instructions of the various program module(s), applications, engines, or the like of the computing system(s) 600 to cause or facilitate various operations to be performed in accordance with one or more embodiments of the disclosure. The processor(s) 602 may include any suitable processing unit capable of accepting data as input, processing the input data in accordance with stored computer-executable instructions, and generating output data. The processor(s) 602 may include any type of suitable processing unit including, but not limited to, a central processing unit, a microprocessor, a Reduced Instruction Set Computer (RISC) microprocessor, a Complex Instruction Set Computer (CISC) microprocessor, a microcontroller, an Application Specific Integrated Circuit (ASIC), a Field-Programmable Gate Array (FPGA), a System-on-a-Chip (SoC), a digital signal processor (DSP), and so forth. Further, the processor(s) 602 may have any suitable microarchitecture design that includes any number of constituent components such as, for example, registers, multiplexers, arithmetic logic units, cache controllers for controlling read/write operations to cache memory, branch predictors, or the like. The microarchitecture design of the processor(s) 602 may be capable of supporting any of a variety of instruction sets.

Referring now to other illustrative components depicted as being stored in the data storage 620, the O/S 622 may be loaded from the data storage 620 into the memory 604 and may provide an interface between other application software executing on the computing system(s) 600 and the hardware resources of the computing system(s) 600. More specifically, the O/S 622 may include a set of computer-executable instructions for managing the hardware resources of the computing system(s) 600 and for providing common services to other application programs (e.g., managing memory allocation among various application programs). In certain example embodiments, the O/S 622 may control execution of the other program module(s). The O/S 622 may include any operating system now known or which may be developed in the future including, but not limited to, any server operating system, any mainframe operating system, or any other proprietary or non-proprietary operating system.

The DBMS 624 may be loaded into the memory 604 and may support functionality for accessing, retrieving, storing, and/or manipulating data stored in the memory 604 and/or data stored in the data storage 620. The DBMS 624 may use any of a variety of database models (e.g., relational model, object model, etc.) and may support any of a variety of query languages. The DBMS 624 may access data represented in one or more data schemas and stored in any suitable data repository including, but not limited to, databases (e.g., relational, object-oriented, etc.), file systems, flat files, distributed datastores in which data is stored on more than one node of a computer network, peer-to-peer network datastores, or the like. In those example embodiments in which the computing system(s) 600 is a mobile device, the DBMS 624 may be any suitable lightweight DBMS optimized for performance on a mobile device.

Referring now to other illustrative components of the computing system(s) 600, the input/output (I/O) interface(s) 606 may facilitate the receipt of input information by the computing system(s) 600 from one or more I/O devices as well as the output of information from the computing system(s) 600 to the one or more I/O devices. The I/O devices may include any of a variety of components such as a display or display screen having a touch surface or touchscreen; an audio output device for producing sound, such as a speaker; an audio capture device, such as a microphone; an image and/or video capture device, such as a camera; a haptic unit; and so forth. Any of these components may be integrated into the computing system(s) 600 or may be separate. The I/O devices may further include, for example, any number of peripheral devices such as data storage devices, printing devices, and so forth.

The I/O interface(s) 606 may also include an interface for an external peripheral device connection such as universal serial bus (USB), Fire Wire, Thunderbolt, Ethernet port or other connection protocol that may connect to one or more networks. The I/O interface(s) 606 may also include a connection to one or more of the antenna(s) 630 to connect to one or more networks via a wireless local area network (WLAN) (such as Wi-Fi) radio, Bluetooth, ZigBee, and/or a wireless network radio, such as a radio capable of communication with a wireless communication network such as a Long Term Evolution (LTE) network, WiMAX network, 3G network, a ZigBee network, etc.

The computing system(s) 600 may further include one or more network interface(s) 608 via which the computing system(s) 600 may communicate with any of a variety of other systems, platforms, networks, devices, and so forth. The network interface(s) 608 may enable communication, for example, with one or more wireless routers, one or more host servers, one or more web servers, and the like via one or more networks.

The antenna(s) 630 may include any suitable type of antenna depending, for example, on the communications protocols used to transmit or receive signals via the antenna(s) 630. Non-limiting examples of suitable antennas may include directional antennas, non-directional antennas, dipole antennas, folded dipole antennas, patch antennas, multiple-input multiple-output (MIMO) antennas, or the like. The antenna(s) 630 may be communicatively coupled to one or more transceivers 612 or radio components to which or from which signals may be transmitted or received.

As previously described, the antenna(s) 630 may include a cellular antenna configured to transmit or receive signals in accordance with established standards and protocols, such as Global System for Mobile Communications (GSM), 3G standards (e.g., Universal Mobile Telecommunications System (UMTS), Wideband Code Division Multiple Access (W-CDMA), CDMA2000, etc.), 4G standards (e.g., Long-Term Evolution (LTE), WiMax, etc.), direct satellite communications, or the like.

The antenna(s) 630 may additionally, or alternatively, include a Wi-Fi antenna configured to transmit or receive signals in accordance with established standards and protocols, such as the IEEE 802.11 family of standards, including via 2.4 GHz channels (e.g., 802.11b, 802.11 g, 802.11n), 5 GHz channels (e.g., 802.11n, 802.11ac), or 60 GHz channels (e.g., 802.1 lad). In alternative example embodiments, the antenna(s) 630 may be configured to transmit or receive radio frequency signals within any suitable frequency range forming part of the unlicensed portion of the radio spectrum.

The antenna(s) 630 may additionally, or alternatively, include a GNSS antenna configured to receive GNSS signals from three or more GNSS satellites carrying time-position information to triangulate a position therefrom. Such a GNSS antenna may be configured to receive GNSS signals from any current or planned GNSS such as, for example, the Global Positioning System (GPS), the GLONASS System, the Compass Navigation System, the Galileo System, or the Indian Regional Navigational System.

The transceiver(s) 612 may include any suitable radio component(s) for—in cooperation with the antenna(s) 630—transmitting or receiving radio frequency (RF) signals in the bandwidth and/or channels corresponding to the communications protocols utilized by the computing system(s) 600 to communicate with other devices. The transceiver(s) 612 may include hardware, software, and/or firmware for modulating, transmitting, or receiving—potentially in cooperation with any of antenna(s) 630—communications signals according to any of the communications protocols discussed above including, but not limited to, one or more Wi-Fi and/or Wi-Fi direct protocols, as standardized by the IEEE 802.11 standards, one or more non-Wi-Fi protocols, or one or more cellular communications protocols or standards. The transceiver(s) 612 may further include hardware, firmware, or software for receiving GNSS signals. The transceiver(s) 612 may include any known receiver and baseband suitable for communicating via the communications protocols utilized by the computing system(s) 600. The transceiver(s) 612 may further include a low noise amplifier (LNA), additional signal amplifiers, an analog-to-digital (A/D) converter, one or more buffers, a digital baseband, or the like.

The sensor(s)/sensor interface(s) 610 may include or may be capable of interfacing with any suitable type of sensing device such as, for example, inertial sensors, force sensors, thermal sensors, photocells, and so forth. Example types of inertial sensors may include accelerometers (e.g., MEMS-based accelerometers), gyroscopes, and so forth.

The optional display(s) 614 may be configured to output light and/or render content. The optional speaker(s)/microphone(s) 616 may be any device configured to receive analog sound input or voice data.

It should be appreciated that the program module(s), applications, computer-executable instructions, code, or the like depicted in FIG. 6 as being stored in the data storage 620 are merely illustrative and not exhaustive and that processing described as being supported by any particular module may alternatively be distributed across multiple module(s) or performed by a different module. In addition, various program module(s), script(s), plug-in(s), Application Programming Interface(s) (API(s)), or any other suitable computer-executable code hosted locally on the computing system(s) 600, and/or hosted on other computing device(s) accessible via one or more networks, may be provided to support functionality provided by the program module(s), applications, or computer-executable code depicted in FIG. 6 and/or additional or alternate functionality. Further, functionality may be modularized differently such that processing described as being supported collectively by the collection of program module(s) depicted in FIG. 6 may be performed by a fewer or greater number of module(s), or functionality described as being supported by any particular module may be supported, at least in part, by another module. In addition, program module(s) that support the functionality described herein may form part of one or more applications executable across any number of systems or devices in accordance with any suitable computing model such as, for example, a client-server model, a peer-to-peer model, and so forth. In addition, any of the functionality described as being supported by any of the program module(s) depicted in FIG. 6 may be implemented, at least partially, in hardware and/or firmware across any number of devices.

It should further be appreciated that the computing system(s) 600 may include alternate and/or additional hardware, software, or firmware components beyond those described or depicted without departing from the scope of the disclosure. More particularly, it should be appreciated that software, firmware, or hardware components depicted as forming part of the computing system(s) 600 are merely illustrative and that some components may not be present or additional components may be provided in various embodiments. While various illustrative program module(s) have been depicted and described as software module(s) stored in the data storage 620, it should be appreciated that functionality described as being supported by the program module(s) may be enabled by any combination of hardware, software, and/or firmware. It should further be appreciated that each of the above-mentioned module(s) may, in various embodiments, represent a logical partitioning of supported functionality. This logical partitioning is depicted for case of explanation of the functionality and may not be representative of the structure of software, hardware, and/or firmware for implementing the functionality. Accordingly, it should be appreciated that functionality described as being provided by a particular module may, in various embodiments, be provided at least in part by one or more other module(s). Further, one or more depicted module(s) may not be present in certain embodiments, while in other embodiments, additional module(s) not depicted may be present and may support at least a portion of the described functionality and/or additional functionality. Moreover, while certain module(s) may be depicted and described as sub-module(s) of another module, in certain embodiments, such module(s) may be provided as independent module(s) or as sub-module(s) of other module(s).

Program module(s), applications, or the like disclosed herein may include one or more software components including, for example, software objects, methods, data structures, or the like. Each such software component may include computer-executable instructions that, responsive to execution, cause at least a portion of the functionality described herein (e.g., one or more operations of the illustrative methods described herein) to be performed.

A software component may be coded in any of a variety of programming languages. An illustrative programming language may be a lower-level programming language such as an assembly language associated with a particular hardware architecture and/or operating system platform. A software component comprising assembly language instructions may require conversion into executable machine code by an assembler prior to execution by the hardware architecture and/or platform.

Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query or search language, or a report writing language. In one or more example embodiments, a software component comprising instructions in one of the foregoing examples of programming languages may be executed directly by an operating system or other software component without having to be first transformed into another form.

A software component may be stored as a file or other data storage construct. Software components of a similar type or functionally related may be stored together such as, for example, in a particular directory, folder, or library. Software components may be static (e.g., pre-established or fixed) or dynamic (e.g., created or modified at the time of execution).

Software components may invoke or be invoked by other software components through any of a wide variety of mechanisms. Invoked or invoking software components may comprise other custom-developed application software, operating system functionality (e.g., device drivers, data storage (e.g., file management) routines, other common routines and services, etc.), or third-party software components (e.g., middleware, encryption, or other security software, database management software, file transfer or other network communication software, mathematical or statistical software, image processing software, and format translation software).

Software components associated with a particular solution or system may reside and be executed on a single platform or may be distributed across multiple platforms. The multiple platforms may be associated with more than one hardware vendor, underlying chip technology, or operating system. Furthermore, software components associated with a particular solution or system may be initially written in one or more programming languages, but may invoke software components written in another programming language.

Computer-executable program instructions may be loaded onto a special-purpose computer or other particular machine, a processor, or other programmable data processing apparatus to produce a particular machine, such that execution of the instructions on the computer, processor, or other programmable data processing apparatus causes one or more functions or operations specified in the flow diagrams to be performed. These computer program instructions may also be stored in a computer-readable storage medium (CRSM) that upon execution may direct a computer or other programmable data processing apparatus to function in a particular manner, such that the instructions stored in the computer-readable storage medium produce an article of manufacture including instruction means that implement one or more functions or operations specified in the flow diagrams. The computer program instructions may also be loaded onto a computer or other programmable data processing apparatus to cause a series of operational elements or steps to be performed on the computer or other programmable apparatus to produce a computer-implemented process.

Additional types of CRSM that may be present in any of the devices described herein may include, but are not limited to, programmable random access memory (PRAM), SRAM, DRAM, RAM, ROM, electrically erasable programmable read-only memory (EEPROM), flash memory or other memory technology, compact disc read-only memory (CD-ROM), digital versatile disc (DVD) or other optical storage, magnetic cassettes, magnetic tape, magnetic disk storage or other magnetic storage devices, or any other medium which can be used to store the information and which can be accessed. Combinations of any of the above are also included within the scope of CRSM. Alternatively, computer-readable communication media (CRCM) may include computer-readable instructions, program module(s), or other data transmitted within a data signal, such as a carrier wave, or other transmission. However, as used herein, CRSM does not include CRCM.

Although embodiments have been described in language specific to structural features and/or methodological acts, it is to be understood that the disclosure is not necessarily limited to the specific features or acts described. Rather, the specific features and acts are disclosed as illustrative forms of implementing the embodiments. Conditional language, such as, among others, “can,” “could,” “might,” or “may,” unless specifically stated otherwise, or otherwise understood within the context as used, is generally intended to convey that certain embodiments could include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

That which is claimed is:

1. A computer-implemented method for converting a high-precision floating point number format to a microscaling (MX) format, the method comprising:
receiving, by a processor, a vector including a first value and a second value, wherein the first value is represented as a first binary value in a high-precision floating point number format, and the second value is represented as a second binary value in the high-precision floating point number format;
determining, by the processor, that an absolute value of the first value is greater than an absolute value of the second value;
determining, by the processor, that a third value satisfies a threshold value, wherein the third value is based on a mantissa of the first binary value;
adjusting, by the processor and based on the determination that the third value satisfies the threshold value, the first value to a fourth value;
determining, by the processor, a fifth value as a difference between a log of the fourth value and a sixth value;
determining, by the processor, a seventh value by removing any values after a decimal point in the sixth value; and
determining, by the processor, a scale value for data in the vector in the MX format based on the seventh value.

2. The computer-implemented method of claim 1, further comprising:
determining that the third value fails to satisfy the threshold value; and
determining, based on the determination that the third value fails to satisfy the threshold value, the fifth value as a difference between a log of the third value and the sixth value.

3. The computer-implemented method of claim 1, wherein the sixth value is a fixed value that is based on a type of MX format.

4. The computer-implemented method of claim 1, wherein determining that the third value satisfies the threshold value further comprises determining that the third value is greater than or equal to the threshold value.

5. The computer-implemented method of claim 4, wherein the threshold value is 1.75.

6. The computer-implemented method of claim 4, wherein the threshold value is a decimal value including a value of 1 and the mantissa value after a decimal following the value of 1.

7. The computer-implemented method of claim 1, wherein the scale value is determined as two to a power of the seventh value.

8. The computer-implemented method of claim 1, wherein the high-precision floating point number format is an FP32 number format.

9. A computer-implemented method for converting a high-precision floating point number format to a microscaling (MX) format, the method comprising:
receiving, by a processor, a vector including a first value and a second value, wherein the first value is represented as a first binary value in a high-precision floating point number format, and the second value is represented as a second binary value in the high-precision floating point number format;
determining, by the processor, that an absolute value of the first value is greater than an absolute value of the second value;
determining a fourth value as a difference between a log of the first value and a third value;
determining a fifth value by either removing any values after a decimal point in the fourth value or increasing the fourth value by one and removing any values after the decimal point; and
determining a scale value for data in the vector in the MX format based on the fifth value.

10. The computer-implemented method of claim 9, wherein the fifth value is a fixed value that is based on a type of MX format.

11. The computer-implemented method of claim 9, wherein the scale value is determined as two to a power of the fifth value.

12. The computer-implemented method of claim 9, wherein the high-precision floating point number format is an FP32 number format.

13. A system for converting a high-precision floating point number format to a microscaling (MX) format, the system comprising:
at least one processor; and
memory storing computer-executable instructions, that when executed by the at least one processor, cause the at least one processor to:
receive a vector including a first value and a second value, wherein the first value is represented as a first binary value in a high-precision floating point number format, and the second value is represented as a second binary value in the high-precision floating point number format;
determine that an absolute value of the first value is greater than an absolute value of the second value;
determine that a third value satisfies a threshold value, wherein the third value is based on a mantissa of the first binary value;
adjust, based on the determination that the third value satisfies the threshold value, the third value to a fourth value;
determine a fifth value as a difference between a log of the fourth value and a sixth value;
determine a seventh value by removing any values after a decimal point in the sixth value; and
determine a scale value for data in the vector in the MX format based on the seventh value.

14. The system of claim 13, wherein the computer-executable instructions further cause the at least one processor to:
determine that the third value fails to satisfy the threshold value; and
determine, based on the determination that the third value fails to satisfy the threshold value, the fifth value as a difference between a log of the third value and the sixth value.

15. The system of claim 13, wherein the sixth value is a fixed value that is based on a type of MX format.

16. The system of claim 13, wherein determining that the third value satisfies the threshold value further comprises determining that the third value is greater than or equal to the threshold value.

17. The system of claim 16, wherein the threshold value is 1.75.

18. The system of claim 16, wherein the threshold value is a decimal value including a value of 1 and the mantissa value after a decimal following the value of 1.

19. The system of claim 13, wherein the scale value is determined as two to a power of the seventh value.

20. The system of claim 13, wherein the high-precision floating point number format is an FP32 number format.
